(19) United States
(12) Patent Application Publication
(10) Pub. No.: US 2019/0390336 A1
(43) Pub. Date: Dec. 26, 2019

(54) TRANSPORT RING

(71) Applicant: AIXTRON SE, Herzogenrath (DE)

(72) Inventors: Wilhelm Josef Thomas KRÜCKEN, Aachen (DE); Martin EICKELKAMP, Würselen (DE)

(21) Appl. No.: 16/480,596

(22) PCT Filed: Jan. 25, 2018
(86) PCT No.: PCT/EP2018/051827

§ 371 Date: Sep. 16, 2019

(30) Foreign Application Priority Data
Jan. 27, 2017 (DE) 10 2017 101 648.1
Jul. 10, 2017 (DE) 10 2017 115 416.7

(51) Int. Cl. C23C 16/458

(52) U.S. Cl. CPC C23C 16/4585

(57) ABSTRACT

A device for transporting a substrate includes a ring-shaped body at least partially surrounding a ring opening. The ring-shaped body includes a first section protruding radially outwards in relation to the ring opening and a second section protruding radially inwards. The first and second sections each have heat transfer properties that determine an axial heat transfer through the sections with an axial temperature difference in relation to a normal of the surface of the ring opening. At least one of the heat transfer properties of the first and second sections is different from one another such that the heat flowing through a unit area element in the axial direction is lower in the first section than in the second section. The heat transfer property refers to the specific heat conductivity or the emissivity of at least one surface of the first and second sections pointing in the axial direction,

### RELATED APPLICATIONS

This application is a National Stage under 35 USC 371 of and claims priority to International Application No. PCT/EP2018/051827, filed 25 Jan. 2018, which claims the priority benefit of DE Application No. 10 2017 101 648.1, filed 27 Jan. 2017 and DE Application No. 10 2017 115 416.7, filed 10 Jul. 2017.

### TECHNICAL FIELD

The invention pertains to a device for transporting a substrate in the form of a ring-shaped body that at least partially surrounds a ring opening, wherein said device comprises a first section that protrudes radially outward with respect to the ring opening and a second section that protrudes radially inward, and wherein the sections respectively have first and second specific heat transfer properties that define an axial heat transfer through the sections at an axial temperature difference with respect to a surface normal of the surface of the ring opening.

### PRIOR ART

WO 2012/096466 A2 discloses a CVD reactor, in which a plurality of substrate holders are arranged on a susceptor that in turn is rotatably arranged in a process chamber. The substrate holders flatly lie on the upwardly facing broadside of a susceptor, which is heated from below, in a temperature-transferring manner. A substrate, particularly a semiconductor substrate, lies on the upwardly facing broadside of the substrate holder, wherein said substrate is coated by means of a process gas that is fed into the process chamber arranged above the susceptor. A gripper is provided for placing the substrates on the upper sides of the substrate holders and for once again removing the substrates from the substrate holders in an automated manner, wherein said gripper has two gripping arms that engage underneath the edge of a transport ring, which lies on a ring step of the substrate holder and engages underneath the outer edge of the substrate with a section that points radially inward. A section of the transport ring, which points radially outward, protrudes over the lateral surface of the substrate holder, which defines a lateral edge, such that the two gripping arms of the gripper can engage underneath the outwardly pointing section of the transport ring.

The coating process takes place in a process chamber, the upper wall of which is cooled, such that a steep temperature gradient is formed between the heated susceptor and the process chamber ceiling. The temperature gradient results in a heat flow from the susceptor to the process chamber ceiling, wherein said heat flow takes place in the form of heat radiation, as well as in the form of heat conduction via the substrate holder and the substrate lying thereon, due to the high susceptor temperatures in excess of 500 degrees Celsius, in certain processes even in excess of 1000 degrees Celsius.

A similar device is described in DE 10 2004 058 521 A1. However, the substrate does not lie on a second section of the transport ring in this case. In fact, the transport ring carries a ring-shaped supporting element, which protrudes radially inward and on which the outer edge of the substrate is supported.

### SUMMARY OF THE INVENTION

The invention is based on the objective of enhancing the transport ring in such a way that the layer deposited on the substrate has a greater lateral homogeneity.

Model calculations have shown that the first section, which protrudes radially outward and serves for the support on gripping arms of a gripper, is in a conventional arrangement of a transport ring in a CVD reactor heated to a lower temperature than the second section, which protrudes radially inward and serves for engaging underneath the edge of the substrate. As a result of the heat conductivity of the body forming the transport ring, heat flows from the second section to the first section such that the edge region of the substrate has a lower surface temperature than the central region of the substrate, which is arranged above an upwardly facing broadside of the substrate holder and particularly lies on this broadside surface in a contacting manner. As a result of this temperature difference, the growth conditions in the edge region differ from those in the central region, which in turn leads to a stoichiometric composition of the layer deposited on the substrate, the layer thickness or doping of which has an inhomogeneity at least in the edge region. On the one hand, the transport ring should have a high heat conductivity in the region carrying the edge of the substrate such that heat made available by the susceptor flows as far as into the edge of the substrate via the substrate holder and the transport ring in order to heat the edge of the substrate to the same temperature, to which the central region of the substrate is heated. On the other hand, the heat loss from the section of the transport ring carrying the substrate in the direction of the transport ring section required for the support on the gripper should be minimized.

According to the invention, the sections of the body should have different heat transfer properties. The definition of the distances is based on an imaginary axis, which extends in the direction of the surface normal of the surface of the ring opening that is at least partially surrounded by the body. According to the invention, the first section, which serves for being supported on the gripping arms of the gripper, is a section that protrudes radially outward. According to the invention, the second section, which particularly forms a step of reduced thickness on which the edge of the substrate lies, is a section that protrudes radially inward. The heat transfer through the body takes place in the axial direction, namely from a downwardly facing broadside of the body in the direction of a broadside of the body, which faces upward toward the process chamber ceiling. The heat transfer properties particularly may be the specific heat conductivities of the sections or the emissivities of the surfaces of the sections. According to the invention, at least one of the heat transfer properties differs in the first section and in the second section in such a way that the heat flowing through a unit area element in the axial direction is lower in the first section than in the second section. The first section, which is arranged radially outward, therefore has a greater resistance to heat flow than the second section, which supports the edge of the substrate in a contacting manner. The emissivity of the surface of the first section may alternatively or additionally be lower than the emissivity of the second section. The body forming the transport ring may be a ring. The ring-shaped body may form a closed ring or an open ring. The first section may border directly on the second section. The boundary between the first section and the second section may extend in the region of the ring step of the substrate holder, on which the ring-shaped body lies. However, the boundary may also lie directly above the edge, i.e. the lateral surface of the substrate holder. The boundary may furthermore lie in a region of the ring-shaped body that protrudes radially outward over the edge of the substrate holder. According to an enhancement of the invention, it is proposed that the first section does not border directly on the second section, but that an intermediate section rather extends between the first section and the second section. This third section may have the same heat transfer properties, particularly the same resistance to heat flow, as the second section, i.e. the section on which the substrate lies with its edge. The boundary between the first section and the second section may lie on the ring step of the substrate holder. It is preferred that the first section completely protrudes radially outward over the substrate holder. It therefore protrudes freely over a lateral surface of the substrate holder such that it is radiantly heated by the surface of the susceptor. As a result of the inventive design of the transport ring, the escape of energy in the form of heat from the ring-shaped body is reduced in comparison with the prior art. The above-described cooling effect is thereby reduced such that the edge temperature of the substrate deviates from the central temperature of the substrate to a lesser extent. The reduced heat conductivity results in less heat flowing from the second section, which is heated due to its contact with the substrate holder, to the first region, in which the heat essentially is dissipated in the form of radiation or in the form of heat conduction via the gas located in the process chamber. It is particularly proposed that the upwardly facing broadside surface of the first section has a lower emissivity, which also results in a reduced energy output in the form of radiation in the direction of the cooled process chamber ceiling. The ring-shaped body, which represents a means for handling the substrate with a gripper, preferably is joined of multiple components, wherein the components have different heat conductivities or their surfaces have different emissivities. The first section preferably is formed by a ring element or by multiple ring elements that have a low specific heat conductivity. The radially outer section therefore comprises one or more ring elements of quartz, zirconium oxide or another material such that it has a lower specific heat conductivity than the material of the section protruding radially inward. The section protruding radially inward may form a base body that has a high specific heat conductivity. This base body may consist of graphite, silicon carbide or another material with high heat conductivity. The different emissivities not only can be defined by the material selection. It is also possible to coat the surfaces of the sections differently. It is also proposed that particularly the first section comprises a reflection element. The reflection element may be a metal strip that is outwardly encapsulated, wherein the encapsulation may be realized with a transparent material. The first section may consist of one or more ring elements of a transparent material and/or with low heat conductivity. The ring elements encapsulate a reflective layer that may be realized in the form of a metal layer. The emissivity of the surface of the first section may be lower than 0.3. The emissivity of the surface of the second section and/or the third section is greater than 0.3. In this context, the surface facing the process chamber ceiling is relevant. The specific heat conductivities may differ by a factor of 10. The specific heat conductivity of the second section preferably is at least 10-times as high as the specific heat conductivity of the first section. In a preferred variation of the invention, it is proposed that a base body of a material with high heat conductivity, for example graphite or zirconium oxide, extends over the entire radial width of the ring-shaped body. The base body therefore forms the second section. The base body forms a carrying section of the first section, on which a ring-shaped element with low heat conductivity and/or high reflectivity is arranged. The first section and the third section jointly form a surface facing the process chamber ceiling. The first section likewise forms a surface facing the process chamber ceiling, wherein the surface of the first section preferably is at least twice as large as the surface of the third section. The boundary between the third section and the second section may lie in the region of a boundary surface of the supporting zone, on which the edge of the substrate lies. Consequently, the third section preferably has a greater axially measured thickness than the second section, wherein the first section preferably has the same axial thickness as the third section. However, the first and the third section differ with respect to their resistance to heat flow. In a preferred embodiment of the invention, the ring-shaped body consists of multiple ring-shaped components that preferably are only arranged on top of one another in the radially outer region. These components may have different heat conductivities. However, it is also proposed that the ring-shaped body consists of multiple ring-shaped elements, wherein a gap is provided between the ring-shaped elements. According to the invention, the gap height is defined by spacer elements. In this case, it is also preferred that the ring elements are only provided in the radially outer region. The spacer elements may be projections that protrude from a broadside surface of the ring element. However, the projections may also protrude from a broadside surface of the base body such that a ring element is supported on the projections. The projections are preferably realized in the form of hemispherical elevations. The projections may be formed by the base body or the ring element and consist of the same material.

### BRIEF DESCRIPTION OF THE DRAWINGS

The invention is described in greater detail below with reference to exemplary embodiments. In the drawings:

FIG. 1 shows a schematic top view of a susceptor arrangement in a CVD reactor,

FIG. 2 shows a section along the line II-II in FIG. 1,

FIG. 3 shows a second exemplary embodiment in the form of an illustration according to FIG. 2,

FIG. 4 shows a third exemplary embodiment in the form of an illustration according to FIG. 3,

FIG. 5 shows a fourth exemplary embodiment of the invention according to FIG. 3, and

FIG. 6 shows a fifth exemplary embodiment according to FIG. 4.

### DESCRIPTION OF THE EMBODIMENTS

The invention pertains to a device for depositing crystalline or non-crystalline layers, particularly semiconductor layers, on a substrate 11 that lies on a supporting surface 13 of a substrate holder 12 with its underside. The lower broadside surface 14 of the substrate holder 12, which has the shape of a circular disk, lies on an upwardly facing surface 17 of a susceptor 16, which is heated from below with not-shown heating elements, in a contacting manner.

A process chamber, into which process gases can be fed by means of a not-shown gas inlet element, is located above the substrate 11, wherein said process gases decompose pyrolytically either in the process chamber or on the surface of the heated substrate 11. The decomposition products react with one another and particularly form a crystalline layer that may consist of two, three or more components.

The top of the process chamber is formed by a process chamber ceiling 19 that is cooled with not-shown cooling elements.

The susceptor temperature Tₛ lies between 500 degrees and 1000 degrees Celsius. The temperature T_{c} of the process chamber ceiling 19 lies in the range between 100 degrees and 300 degrees Celsius. As a result of this temperature difference, a vertical temperature gradient is formed between the upper side 17 of the susceptor 16 and the process chamber ceiling 19 and results in heat flowing from the susceptor 16 to the process chamber ceiling 19. This takes place in the form of heat radiation on the one hand, but also in the form of heat conduction via the substrate holder 12, which consists of a material with high heat conductivity such as graphite.

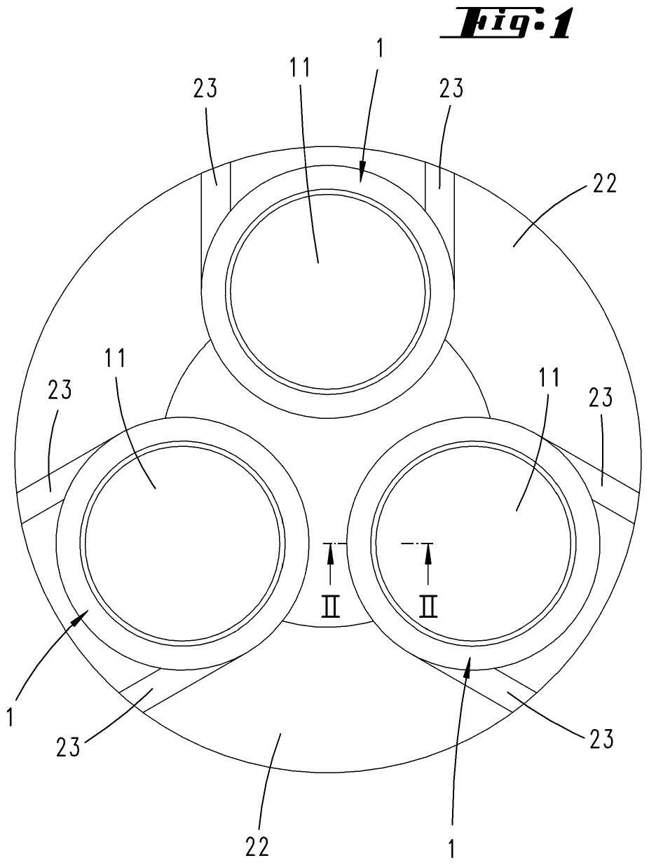

FIG. 1 shows a top view of a bottom of a process chamber. Multiple substrate holders 12, which have the shape of a circular disk and are not visible in FIG. 1, lie on a susceptor 16, which is heated from below and also not visible in this figure. A ring-shaped body 1 that forms a transport ring respectively rests on a ring step 15, which forms a carrying surface and is likewise not visible in FIG. 1. The individual substrate holders 12 are surrounded by intermediate pieces 21, 22, which fill out the surface between the individual substrate holders 12 and are made of a material with high heat conductivity such as graphite.

Two channels 23, which essentially extend radially and parallel to one another, are provided in the intermediate pieces 22 for each respective substrate holder 12 or transport ring 1, wherein the arms of a not-shown gripper can engage underneath a lower broadside surface of a first section 2 of the ring-shaped body 1 through said channels in order to lift the ring-shaped body 1. The edge of the substrate 11 rests on a second section 3 of the ring-shaped body 1, which protrudes radially inward, such that the substrate 11 can be removed from the substrate holder 12 by lifting the ring-shaped body 1.

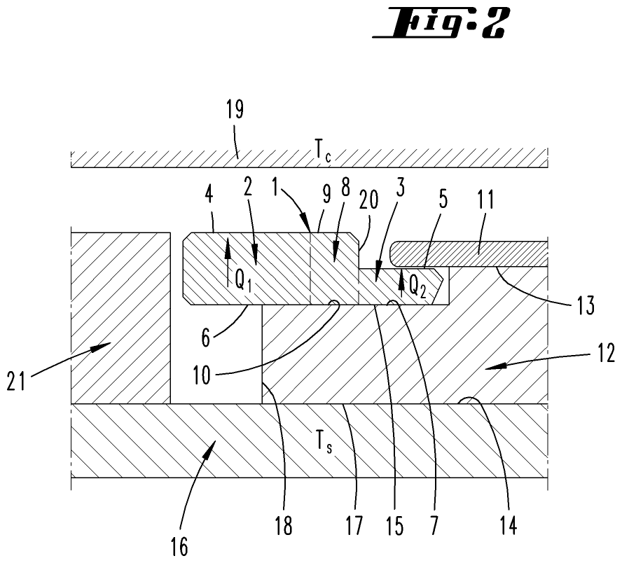

FIG. 2 shows a first exemplary embodiment of the transport ring 1 that has a first section 2, which forms a radially outer section 2 with respect to an axis extending through the surface of the opening of the transport ring 1. The radially outer section 2 has an upper broadside surface that faces the process chamber ceiling 19 and a lower broadside surface 6 that faces the susceptor 16, wherein the lower broadside surface 6 lies directly opposite of the upper side 17 of the susceptor 16 and therefore receives heat radiation emitted by the susceptor 16. The heat flow Q₁ flows through the first section 2 in the axial direction and essentially is emitted from the upper broadside surface 4 in the direction of the process chamber ceiling 19 in the form of heat radiation.

A second section 3, which protrudes radially inward, has a smaller axial thickness than the first section 2. The second section 3 has a downwardly facing broadside surface 7, by means of which the second section 3 lies on an upwardly facing ring step 15 of the substrate holder 12. The edge of the substrate 11 rests on an upwardly facing broadside surface that forms a supporting surface 5.

The substrate 11 is heated to a process temperature in the form of heat conduction via the substrate holder 12 and in the form of heat conduction via the supporting surface 13. The edge of the substrate 11 is heated by the heat flow Q₂ through the second section 3, namely by the heat flow from the broadside surface 7 to the supporting surface 5. The heat transfer from the susceptor 16 to the first section 2 is lower than the heat transfer from the susceptor 16 to the second section 3 such that heat emitted from the broadside surface 4 toward the process chamber ceiling 19 in the form of heat radiation has the tendency to flow from the second section 3 to the first section 2. In order to reduce this vertical or radial heat flow within the transport ring 1, it is proposed that the heat conductivity of the second section 3 is greater than the heat conductivity of the first section 2.

The second section 3 may border directly on the first section 2.

However, a third section 8 is provided between the first section 2 and the second section 3 in the exemplary embodiment illustrated in FIG. 2. The third section 8 has an upwardly facing broadside surface 9 that ends flush with the broadside surface 4. A downwardly facing broadside surface 10 of the third section 8 ends flush with the broadside surface 6 of the first section 2.

The second section 3 borders on the third section 8 in the region of a vertical boundary surface 20, which defines the region of the second section 3 with reduced thickness. The boundary surface 20 forms a step.

The material properties of the second section 3 essentially are identical to the material properties of the third section 8. The material properties of the first section 2 differ from the material properties of the second section 3 in that the resistance to heat flow of the first section 2 is greater than the resistance to heat flow of the second section 3. It is particularly proposed that the heat conductivity of the second section 3 and, if applicable, the third section 8 is greater than the heat conductivity of the first section 2. The first section 2 and the respective second section 3 or third section 8 may be made of different materials. The ring-shaped body 1 may be composed of multiple parts. The parts may be positively or non-positively connected to one another. However, the parts may also be sintered to one another. The body may furthermore be realized in the form of a multi-component body.

In the exemplary embodiment illustrated in FIG. 2, the boundary between the first section 2 and the third section 8 or the boundary between the third section 8 and the second section 3 respectively lies above the ring step 15 of the substrate holder 12.

The upwardly facing broadside surfaces 4, 9 and 5, as well as the downwardly facing broadside surfaces 6, 10 and 7, have an emissivity for infrared radiation and a reflectivity for infrared radiation. The emissivity of the surfaces 4, 6 associated with the first section 2, but at least the emissivity of the upwardly facing broadside surface 4, is lower than the emissivity of the broadside surfaces 5, 7 associated with the second section 3 and the broadside surfaces 9, 10 associated with the third section 8, wherein at least the emissivity of the upwardly facing broadside surface 5 is greater than the emissivity of the upwardly facing broadside surface 4. Accordingly, the broadside surfaces 4, 6 have a greater reflectivity than the respective broadside surfaces 5, 7 and 9, 10.

However, it may suffice if only one of the heat transfer properties heat conductivity, emissivity or reflectivity differs.

FIG. 3 shows a second exemplary embodiment of the invention, in which the ring-shaped body 1 forms a base body 24 that in turn forms the second section, the third section and a lower region of the first section and consists of the same material. The second section 3 essentially differs from the third section 8 in that the axial thickness of the third section is greater than the axial thickness of the second section 3 such that the supporting surface 5 borders on a vertical step 20, which transforms into the upper broadside surface 9 of the third section 8. The lower broadside surfaces 7, 6 flushly transform into one another.

Two ring elements 25, 26 of a transparent material are arranged on a region of the base body 24. The ring elements 25, 26 may consist of quartz. They have a lower heat conductivity than the material of the base body 24, which may be graphite.

A reflection body is arranged between the two ring elements 25, 26. This reflection body may be realized in the form of a metal film that is encapsulated between the two ring elements 25, 26.

The metal film 27 provides the first section 2 or the broadside surface 4 of the first section 2 facing the process chamber ceiling with a greater reflectivity and therefore a lower emissivity than the upwardly facing broadside surfaces 9 or 5 of the second section 3 and the third section 8.

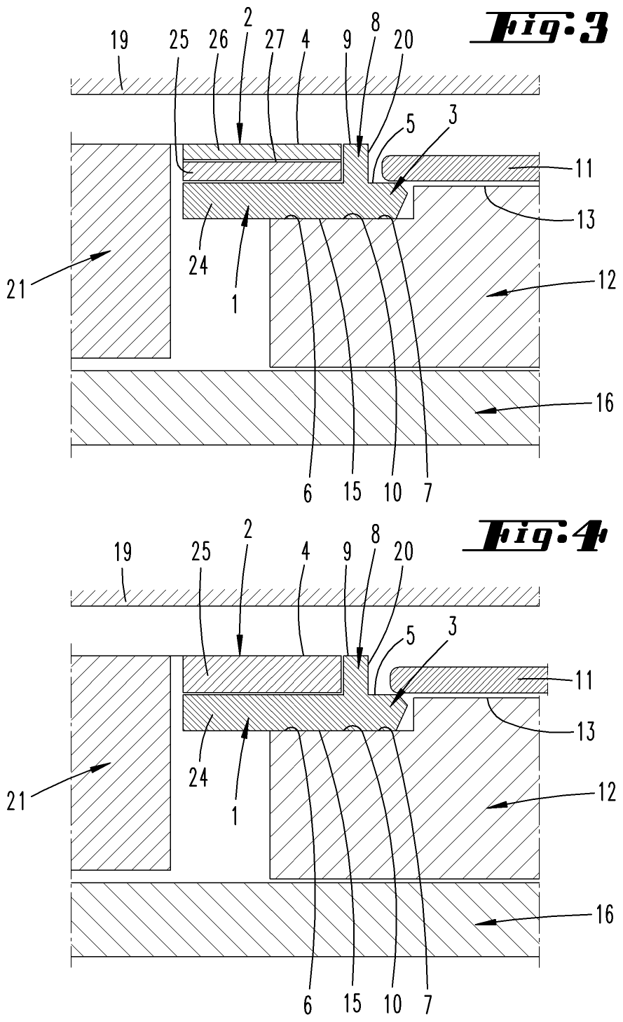

In the third exemplary embodiment illustrated in FIG. 4, the base body 24 forms an extension that extends up to the radially outer edge of the transport ring 1 and just like the extension of the exemplary embodiment illustrated in FIG. 3 forms an upwardly facing supporting surface, which extends at the height of the contact surface 5 and is separated from the contact surface 5 by a ring-shaped web of the third section 8.

In this case, a single ring-shaped body rests on this supporting surface. It is realized in the form of a ring element 25 of a material with low heat conductivity.

It is particularly proposed that the surfaces and especially the surfaces of the transport ring 1 facing the cooled process chamber have different emissivities. The broadside surfaces lying radially outward have a low emissivity and therefore a high reflectivity. In contrast, the radially inner broadside surfaces have a low reflectivity and a high emissivity. In order to achieve stable thermal properties, the emissivity of the respective surfaces or surface coatings should not be altered due to chemical reactions or parasitic depositions. This is achieved by using ring elements that consist of a transparent material with a low heat conductivity such as quartz glass. A reflective layer, particularly a metallic layer, is encapsulated in the ring body and surrounded by a protective transparent material on all sides. The reflectivity should be greater than 60 percent.

It is particularly proposed that a ring-shaped web, which has a high heat conductivity, i.e. a low specific resistance to heat flow, is arranged between the ring element of a material with low heat conductivity and the supporting surface 5. This ensures that the temperature in the edge region of the substrate is increased and the substrate is also laterally heated starting from this rib. The rib forming the third section 8 is heated in the form of heat conduction via the ring step 15. The surface of the first section 2 should be at least exactly as large as the surface of the third section 8, wherein the radial width of the ring-shaped web forming the third section 8 should amount to at least 0.5 mm.

In FIGS. 2 to 4, the substrate holder 12 essentially is illustrated lying on the susceptor 16. However, the substrate holder 12 may also lie in a pocket of the susceptor 16. It is furthermore possible that the substrate holder 12 is rotatably associated with the susceptor 16. For example, gas outlet channels, through which a flushing gas is introduced into the intermediate space between the substrate holder 12 and the susceptor 16, may discharge underneath the broadside surface 14 of the substrate holder 12, wherein said flushing gas forms a gas cushion, on which the substrate holder 12 rests. The substrate holder 12 can be set in rotation with a suitable flow direction of the flushing gas.

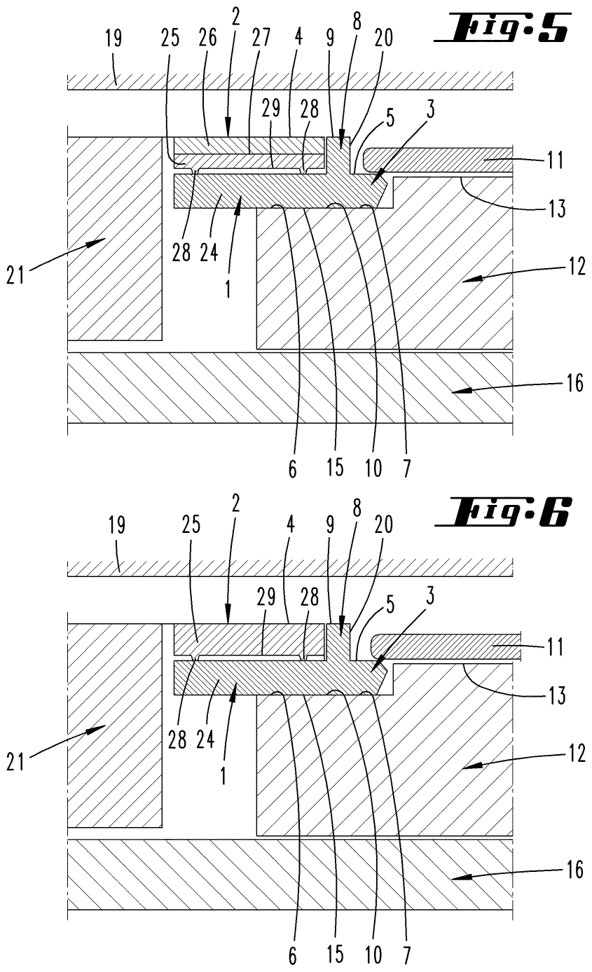

FIG. 5 shows an exemplary embodiment that is realized similar to the exemplary embodiment illustrated in FIG. 3. The base body 24 forms a radially outer supporting surface, which essentially is a horizontal surface. A first ring element 25 lies on this supporting surface. The ring element 25 may consist of the same material as the base body 24. A second ring element 26 is supported on the first ring element 25. The ring element 26 may consist of the same material as the base body 24. A gap 29 extends between the base body 24 and the first ring element 25 lying directly thereon. The gap height of the gap 29 is defined by spacer elements 28. The spacer elements 28 are realized in the form of individual elevations that originate from one of the two broadside surfaces, between which the gap 29 extends.

In the exemplary embodiment, the spacer elements 28 are realized in the form of individual hemispherical elevations of the first ring element 25, on which the second ring element 26 lies. The gap 29 acts as a heat flow insulation gap during the operation of the device.

In a not-shown variation of the fourth exemplary embodiment, additional spacer elements may be provided in order to form a second gap between the first ring element 25 and the second ring element 26.

The fifth exemplary embodiment illustrated in FIG. 6 essentially corresponds to the third exemplary embodiment illustrated in FIG. 4. A ring element 25 is supported on a horizontal surface of the base body 24 in the radially outer region, wherein said ring element may consist of the same material as the base body 24. However, the materials of the base body 24 and the ring element 25 may also differ from one another. A gap 29 between a lower broadside surface of the ring element 25 and an upper broadside surface of the base body 24 is essential. The gap height of the gap 29 is defined by spacer elements 28. In the exemplary embodiment illustrated in FIG. 6, the spacer elements 28 are formed by the ring element 25. They are realized in the form of an knob-like elevations of the downwardly facing broadside surface. The knobs may also have a hemispherical shape in this case.

The preceding explanations serve for elucidating all inventions that are included in this application and respectively enhance the prior art independently with at least the following combinations of characteristics, wherein two, more or all of these combinations of characteristics may also be combined, namely:

A device, which is characterized in that at least one heat transfer property of the first section 2 differs from the heat transfer property of the second section 3 in such a way that the heat flowing through a unit area element in the axial direction is lower in the first section 2 than in the second section 3.

A device, which is characterized in that the heat transfer property is the specific heat conductivity of the section, wherein the specific heat conductivity of the first section 2 is lower than the specific heat conductivity of the second section 3.

A device, which is characterized in that the heat transfer property is the emissivity of at least a surface of the sections 2, 3 pointing in the axial direction, wherein the emissivity of the surface of the first section 2 is lower than the emissivity of the surface of the second section 3.

A device, which is characterized by a third section 8 that is arranged between the first section 2 and the second section 3, wherein the heat transfer properties of said third section essentially correspond to the heat transfer properties of the second section 3.

A device, which is characterized in that the second section 3 and, if applicable, the third section 8 lies on a ring step 15 of a substrate holder 12.

A device, which is characterized in that the substrate holder 12 is carried by a susceptor 16, which is heated from below, and the first section 2 protrudes freely over a lateral surface 18 of the substrate holder 12.

A device, which is characterized in that the ring-shaped body 1 consists of multiple elements 24, 25, 26 that are connected to one another and have different specific heat transfer properties and/or are spaced apart from one another by means of spacer elements (28).

A device, which is characterized in that one or more ring elements 25, 26 associated with the first section 2 have a low specific heat conductivity and particularly consist of quartz or zirconium oxide and a base body 24 associated with at least the second section has a high specific heat conductivity and particularly consists of graphite or silicon carbide.

A device, which is characterized in that the different emissivities of the surfaces are defined by different surface coatings or by at least one reflection element 27.

A device, which is characterized in that one or more ring elements 24, 25 associated with the first section 2 consist of a transparent material with low heat conductivity, in which a reflective layer 27, particularly a metal layer, is encapsulated.

A device, which is characterized in that the specific heat conductivity of the second section 3 is at least ten-times as high as the specific heat conductivity of the first section 2 and/or that the emissivity of the surface 4 of the first section 2 is lower than 0.3 and the emissivity of the surface 5, 9 of the second section 3 and/or the third section 8 is greater than 0.3.

A device, which is characterized in that the ring-shaped body 1 is formed by a base body 24 that extends over the first section 2 and the second section 3, wherein the first section 2 comprises at least one ring element 25, 26 with heat transfer properties that differ from the heat transfer properties of the base body 24.

A device, which is characterized in that the first section 2 and the third section 8 respectively have a surface 4, 9 that faces a process chamber ceiling 19, wherein the surface 4 of the first section 2 is at least twice as large as the surface 9 of the third section 8.

A device, which is characterized in that a surface 5 of the second section 3, which faces the process chamber ceiling 19, forms a supporting zone for supporting the edge of the substrate 11, wherein the supporting zone is surrounded by a boundary surface 20 of the third section 8, which just like the second section 3 lies on the ring step 15 of the substrate holder 12 with a surface 10, 7 facing the susceptor 16.

All disclosed characteristics are essential to the invention (individually, but also in combination with one another). The disclosure content of the associated/attached priority documents (copy of the priority application) is hereby fully incorporated into the disclosure of this application, namely also for the purpose of integrating characteristics of these documents into claims of the present application. The characteristics of the dependent claims characterize independent inventive enhancements of the prior art, particularly for submitting divisional applications on the basis of these claims.

### LIST OF REFERENCE SYMBOLS

1 Ring-shaped body
2 First section
3 Second section
4 Broadside surface
5 Supporting surface
6 Broadside surface
7 Broadside surface
8 Third section
9 Broadside surface
10 Broadside surface
11 Substrate
12 Substrate holder
13 Supporting surface
14 Broadside surface
15 Carrying surface, ring step
16 Susceptor
17 Upper side
18 Lateral surface
19 Process chamber ceiling
20 Boundary surface
21 Intermediate piece
22 Intermediate piece
23 Channel
24 Base body
25 Ring element
26 Ring element
27 Reflection element
28 Spacer element
29 Gap
Tₛ Susceptor temperature
T_{c} Temperature of the process chamber ceiling
Q₁ Heat flow
Q₂ Heat flow

What is claimed is:

1. A ring-shaped body (1) for a chemical vapor deposition (CVD) reactor, the ring-shaped body (1) at least partially surrounding a ring opening and lying on a ring step (15) of a substrate holder (12) carried by a heated susceptor (16), the ring-shaped body (1) comprising:
a first section (2) that protrudes radially outward with respect to the ring opening and has a first, upwardly facing upper broadside surface (4) and a first, downwardly facing broadside surface (6), wherein said first section protrudes over the substrate holder (12) radially outward and receives a first heat flow (Q₁) in the form of heat radiation from an upper side (17) of the susceptor (16); and
a second section (3) that protrudes radially inward with respect to the ring opening and has a second, upwardly facing broadside surface (5) for supporting an edge of the substrate (11) and a second, downwardly facing broadside surface (6) that lies on the upwardly facing ring step (15) such that the edge of the substrate (11) is heated by a second heat flow (Q₂) through the second section (3), and wherein the first and second sections (2, 3) respectively have heat transfer properties that define an axial heat transfer through the first and second sections from the respective first and second lower broadside surfaces (6, 7) to the respective first and second upper broadside surfaces (4, 5) at an axial temperature difference with respect to a surface normal of a surface of the ring opening, wherein at least one heat transfer property of the first section (2) differs from the heat transfer property of the second section (3) in such a way that the heat flowing through a unit area element in an axial direction is lower in the first section (2) than in the second section (3)
wherein the first and second heat flows (Q₁, Q₂) are caused by a temperature difference between an upper side (17) of the susceptor (16) and a process chamber ceiling (19).

2. The ring-shaped body of claim 1, wherein the heat transfer property of the first section (2) is the specific heat conductivity of the first section (2), wherein the heat transfer property of the second section (2) is the specific heat conductivity of the second section (3), and wherein the specific heat conductivity of the first section (2) is lower than the specific heat conductivity of the second section (3).

3. The ring-shaped body of claim 1, wherein the heat transfer property of the first section (2) is an emissivity of the first, upwardly facing broadside surface of the first section (2), wherein the heat transfer property of the second section (3) is an emissivity of the second, upwardly facing broadside surface of the second section (3), and wherein the emissivity of the first, upwardly facing broadside surface of the first section (2) is lower than the emissivity of the second, upwardly facing broadside surface of the second section (3).

4. The ring-shaped body of claim 1, further comprising a third section (8) that is arranged between the first section (2) and the second section (3), wherein heat transfer properties of said third section correspond to the heat transfer properties of the second section (3).

5. The ring-shaped body of claim 4, wherein the second section (3) and the third section (8) lie on the ring step (15) of the substrate holder (12).

6. The CVD reactor of claim 17, wherein the heated susceptor (16) is heated from below, and the first section (2) protrudes freely over a lateral surface (18) of the substrate holder (12).

7. The ring-shaped body of claim 1, wherein the ring-shaped body (1) comprises multiple elements (24, 25, 26), which are:
(i) connected to one another,
(ii) have different specific heat transfer properties, and/or
(iii) are spaced apart from one another by means of spacer elements (28).

8. The ring-shaped body of claim 1, wherein one or more ring elements (25, 26) associated with the first section (2) have a low specific heat conductivity and consist of quartz or zirconium oxide and a base body (24) associated with at least the second section (3) has a high specific heat conductivity and consists of graphite or silicon carbide.

9. The ring-shaped body of claim 3, wherein the different emissivities of the first, second upwardly facing broadside surfaces of the first and second sections, respectively, are defined by different surface coatings or by at least one reflection element (27).

10. The ring-shaped body of claim 3, wherein one or more ring elements (24, 25) associated with the first section (2) consist of a transparent material with low heat conductivity, in which a reflective layer (27) is encapsulated.

11. The ring-shaped body of claim 1, wherein a specific heat conductivity of the second section (3) is at least ten-times as high as a specific heat conductivity of the first section (2).

12. The ring-shaped body of claim 1, wherein an emissivity of the first, upwardly facing broadside surface (4) of the first section (2) is lower than 0.3, and an emissivity of the second, upwardly facing broadside surface (5) of the second section (3) is greater than 0.3.

13. The ring-shaped body of claim 1, further comprising a base body (24) that extends over the first section (2) and the second section (3), wherein the first section (2) comprises at least one ring element (25, 26) with heat transfer properties that differ from heat transfer properties of the base body (24).

14. The ring-shaped body of claim 4, wherein the third section (8) has a third, upwardly facing broadside surface (9), wherein the first, upwardly facing broadside surface (4) of the first section (2) is at least twice as large as the third, upwardly facing broadside surface (9) of the third section (8).

15. The ring-shaped body of claim 4, wherein the second, upwardly facing broadside surface (5) of the second section (3) forms a supporting zone for supporting the edge of the substrate (11), and wherein the supporting zone is surrounded by a boundary surface (20) of the third section (8), which lies on the ring step (15) of the substrate holder (12), the third section having a third, downwardly facing broadside surface (10) facing the susceptor (16).

16. (canceled)

17. A chemical vapor deposition (CVD) reactor, comprising:
a heated susceptor (16);
a substrate holder (12) carried by the heated susceptor (16); and
a ring-shaped body (1) at least partially surrounding a ring opening and lying on a ring step (15) of the substrate holder (12), the ring-shaped body (1) comprising:
a first section (2) that protrudes radially outward with respect to the ring opening and has a first, upwardly facing broadside surface (4) and a first, downwardly facing broadside surface (6), wherein said first section protrudes over the substrate holder (12) radially outward and receives a first heat flow (Q₁) in the form of heat radiation from an upper side (17) of the susceptor (16); and
a second section (3) that protrudes radially inward with respect to the ring opening and has a second, upwardly facing broadside surface (5) for supporting an edge of the substrate (11) and a second, downwardly facing broadside surface (6) that lies on the upwardly facing ring step (15) such that the edge of the substrate (11) is heated by a second heat flow (Q₂) through the second section (3), and wherein the first and second sections (2, 3) respectively have heat transfer properties that define an axial heat transfer through the first and second sections from the respective first and second lower broadside surfaces (6, 7) to the respective first and second upper broadside surfaces (4, 5) at an axial temperature difference with respect to a surface normal of a surface of the ring opening, wherein at least one heat transfer property of the first section (2) differs from the heat transfer property of the second section (3) in such a way that the heat flowing through a unit area element in an axial direction is lower in the first section (2) than in the second section (3), and
wherein the first and second heat flows (Q₁, Q₂) are caused by a temperature difference between an upper side (17) of the susceptor (16) and a process chamber ceiling (19).

18. A method for using a ring-shaped body (1) in a chemical vapor deposition (CVD) reactor, the ring-shaped body (1) at least partially surrounding a ring opening, the ring-shaped body (1) comprising (i) a first section (2) that protrudes radially outward with respect to the ring opening and has a first, upwardly facing broadside surface (4) and a first, downwardly facing broadside surface (6), and (ii) a second section (3) that protrudes radially inward with respect to the ring opening and has a second, upwardly facing broadside surface (5) and a second, downwardly facing broadside surface (7), the method comprising:
supporting, by a heated susceptor (16), a substrate holder (12), wherein the substrate holder (12) comprises a ring step (15);
supporting, by the ring step (15) of the substrate holder (12), a portion of the first, downwardly facing broadside surface (6) of the first section (2);
supporting, by the ring step (15) of the substrate holder (12), the second, downwardly facing broadside surface (7) of the second section (3);
supporting, by the second, upwardly facing broadside surface (5) of the second section (3), an edge of a substrate (11);
receiving, by a portion of the first section (2) that protrudes radially outward over the substrate holder (12), a first heat flow (Q₁) in the form of heat radiation from an upper side (17) of the heated susceptor (16); and
receiving, by the edge of the substrate (11), a second heat flow (Q₂) from the second section (3), wherein the second heat flow (Q₂) flows into the second section (3) from the heated susceptor (16) through the second, downwardly facing broadside surface (7) of the second section (3),
wherein the first and second heat flows (Q₁, Q₂) are caused by a temperature difference between an upper side (17) of the heated susceptor (16) and a process chamber ceiling (19),
wherein the first and second sections (2, 3) respectively have heat transfer properties that define an axial heat transfer through the first and second sections from the respective first and second lower broadside surfaces (6, 7) to the respective first and second upper broadside surfaces (4, 5) at an axial temperature difference with respect to a surface normal of a surface of the ring opening, and
wherein at least one heat transfer property of the first section (2) differs from the heat transfer property of the second section (3) in such a way that the heat flowing through a unit area element in an axial direction is lower in the first section (2) than in the second section (3).
